(19) United States
(12) Patent Application Publication
(10) Pub. No.: US 2025/0080996 A1
(43) Pub. Date: Mar. 6, 2025

(54) NOVEL SCATTERER DENSITY-BASED PREDICTIVE CHANNEL MODELING METHOD

(71) Applicants: Southeast University, Nanjing (CN); PURPLE MOUNTAIN LABORATORIES, Nanjing (CN)

(72) Inventors: Chengxiang WANG, Nanjing (CN); Zheao LI, Nanjing (CN); Chen HUANG, Nanjing (CN); Long YU, Nanjing (CN); Junling LI, Nanjing (CN); Zhongyu QIAN, Nanjing (CN)

(21) Appl. No.: 18/816,784

(22) Filed: Aug. 27, 2024

(30) Foreign Application Priority Data
Aug. 29, 2023 (CN) 2023110970111

(51) Int. Cl. H04W 16/18; H04W 24/00

(52) U.S. Cl. CPC H04W 16/18; H04W 24/00

(57) ABSTRACT

A novel scatterer density-based predictive channel modeling method includes: obtaining channel data with different scenarios scatterer densities through a channel measurement or a simulation; obtaining corresponding channel statistical characteristic parameters through a data preprocessing based on the channel data; constructing a graph dataset by taking scatterer density in different scenarios as main characteristics to enhance a space-time correlation of data; dividing the graph dataset according to a certain proportion, and then using a graph attention network and a gated recurrent unit network to extract correlated channel space-time characteristics and implementing a cross scenario channel prediction. The method can capture channel variations in different scenarios, and obtain channel characteristics under different scatterer densities through high space-time correlated channel characteristics, and has good performance in channel prediction based on scenario.

### TECHNICAL FIELD

The present disclosure belongs to a cross-fusion application field of machine learning (ML) and wireless channel modeling, and in particular relates to a novel scatterer density-based predictive channel modeling method.

### BACKGROUND

The sixth generation wireless communications (6G) system, developed from the fifth generation wireless communications (5G) system, aims to enhance the mobile internet and internet of everything, and deeply integrate with big data to implement the internet of everything. In addition, wireless communication is no longer limited to traditional typical scenarios, but wider vertical industries. Different communication scenarios can lead to dynamic environmental variations between different scenarios and applications, which poses many requirements for communications in complex scenarios. Wireless channel modeling is the foundation of wireless communication system design, theoretical analysis, performance evaluation, and optimization, which can effectively and feasibly simulate the propagation process of radio waves under different communication scenarios. Under the new vision of the sixth generation wireless communications, wireless communication faces unprecedented complexity, requiring more complex channel models to reconstruct complex the sixth generation wireless communications scenarios, and traditional channel modeling methods cannot meet the above requirements. For example, in the massive sixth generation wireless communications scenarios, channel modeling requires a large amount of high-precision channel measurement data for verification. However, channel measurement is costly, time-consuming, and cannot cover all frequency bands and scenarios. In addition, processing a large amount of channel measurement data requires the use of high-resolution parameter estimation methods, resulting in extremely high computational complexity in traditional channel modeling. And traditional channel models cannot flexibly and accurately predict channel characteristics in future time, unknown frequency bands, and unknown scenarios. In view of above problems, there is an urgent need for a new method for modeling predictive channel in the sixth generation wireless communications.

Machine learning is a key technology in the field of artificial intelligence (AI), which enables machines to intelligently learn and acquire new skills from large amounts of data without the need for any specific commands. With the continuous developments of machine learning technology and the continuous expansions of communication data scales, channel modeling based on machine learning is seen as a powerful tool to compensate for the shortcomings of traditional method for modeling wireless channel. Due to the fact that machine learning algorithms can mine hidden information in channel data to analyze and capture different channel characteristics, channel models based on machine learning can predict unknown positions, future time, and unknown frequency bands by extracting potential characteristics from channel measurements or simulation data. According to existing literature, machine-learning-based predictive channel modeling can generally be divided into space domain predictive channel modeling, time domain predictive channel modeling, and frequency domain predictive channel modeling. Space domain predictive channel modeling is expected to explore the relationships between channel characteristics and physical environment parameters, and use channels with known space positions to predict channels with unknown positions. Time domain predictive channel modeling is dedicated to understanding the variation rules of channels over time and predicting future information using known historical channel information. Frequency domain predictive channel modeling explores the similarities and differences in channel characteristics between different frequency bands, implementing cross-band channel characteristic predictive.

However, existing research on space-time-frequency domain predictive channel modeling has not effectively addressed the channel modeling problems in different 6G scenarios. In communication scenarios, when the densities of the scatterers vary, the corresponding channel characteristics will also vary with variations in the environment. While current channel modeling work is difficult to construct a predictive channel model based on the scatterer density considering the dynamic variations of the channels in the scenarios. In addition, traditional methods for modeling channels typically use different model parameters to reconstruct the corresponding channels to accurately capture channel variations in different communication scenarios, which requires further channel measurement data for validations. The existing methods for modeling predictive channel model based on machine learning also have some disadvantages, and there are no comprehensive studies on the impacts of physical environment variations on channel characteristics in different scenarios. In 6G communication, more attention needs to be paid to the channel statistical characteristics caused by dynamic variations in different scatterer densities. Finally, many predictive channel models use all data samples for training without considering the correlations between data samples, which ultimately leads to the problems such as low learning efficiency and long model training time.

### SUMMARY

The objectives of the present disclosure are to provide a novel scatterer density-based predictive channel modeling method, and is used to explore dynamic evolutions of channels in different scatterer density scenarios and can predict channel characteristics in relative high scatterer density scenarios or relative low scatterer density scenarios. This model utilizes high space-time correlation data for training, improving a channel prediction performance across different scenarios and achieving a relative high prediction accuracy. This module is used to explore the dynamic evolutions of channels in different scatterer density scenarios and can predict channel characteristics in the relative high scatterer density scenarios or the relative low scatterer density scenarios. This model utilizes high space-time correlation data for training, improving the prediction performance of the scenario channel based on the scatterer density and achieving the relative high prediction accuracy, so as to solve the technical problems mentioned in the background technology.

In order to achieve above technical problems, the specific technical solutions of the present disclosure are as follows.

Provided is a novel scatterer density-based predictive channel modeling method. And the method includes the following steps.

In Step S1, channel data in a corresponding scenario are collected through a channel measurement or a simulation. In view of different scatterer densities, channel data in the plurality of scenarios are collected for subsequent channel prediction experiments.

In Step S2, in view of the channel data obtained in Step S1, collected channel measurement data are preprocessed by a high-precision channel parameters extraction algorithm to obtain corresponding channel statistical characteristic parameters. Then, physical environment parameters in a current scenario and channel characteristic parameters in the current scenario are combined to form a channel data vector for constructing a dataset subsequently.

In Step S3, a space-time graph dataset for a predictive channel modeling is constructed. The scatterer densities in different scenarios are taken as main characteristics during a network training process, in order to better extract the scatterer densities, in view of the channel data vector obtained in Step S2, space-time correlation of the channel data are enhanced by correlated neighboring nodes and time series, to construct the space-time graph dataset for the channel.

In Step S4, the space-time graph dataset for the channel constructed in a specific scatterer density scenario are divided into a training set, a validation set, and a testing set in proportion, which are taken as inputs of a predictive network.

In Step S5, a cross scenario communication predictive training is performed on a channel prediction network based on a graph attention network (GAT) and a gated recurrent unit GRU. And the training includes as follows. Firstly, the channel prediction network based on GAT-GRU is constructed, and a network parameter configuration of the channel prediction network is initialized. Then, the constructed space-time graph dataset for the channel is input into a GAT-GRU network, to perform the channel prediction, capturing high space-time correlated channel characteristics. An error between output results of the network on the testing set and actual measurement values for the network is calculated, and further parameters for the channel prediction network based on GAT-GRU is fine-tuned according to a result. Finally, predicted channel characteristics in different scatterer density scenarios in the testing set are obtained, and a cross scenario channel prediction is implemented. And —represents combination.

Further, Step S1 specifically includes following steps.

In Step S101, the channel data are simulated by utilizing a ray tracing (RT) Wireless Insite commercial software, indoor office scenarios with different scatterer densities are emulated, and the scatterer densities ρₛ is defined as:

$${ρ}_{s} = \frac{\sum {S}_{{S}_{i}}}{{S}_{total}} \times 100 \% = \frac{\sum {S}_{{S}_{i}}}{\sum {S}_{{S}_{i}} + {S}_{room}} \times 100 \% ,$$

where Sₜₒₜₐₗ denotes a surface area of an entire scenario, Sₛ₁ denotes a surface area of each of the scatterers in the scenario, Sᵣₒₒₘ denotes a surface area of own rooms in the indoor office, and an entire scatterer density formula expresses a percentage of the scatterers in the communication scenario to surface area of the entire scenario.

In a case of an obtained scatterer density ρₛ₁<40% of a simulated communication scenario, it is defined as a sparse scenario; in a case of the obtained scatterer density ρₛ₂40% of the simulated communication scenario, it is defined as a dense scenario.

Further, Step S2 specifically includes following steps.

In Step S201, high-precision channel characteristic parameters are extracted from collected channel data by using a space-alternating generalized expectation maximization algorithm space-alternating generalized expectation maximization (SAGE). And the high-precision channel characteristic parameters include a received power P for describing a signal strength that is obtained from an original channel impulse response, a root mean square (RMS) delay spread RMS DS σ_{ds} for describing channel time dispersion characteristics, a root mean square azimuthal arrival angle spread RMS AAS σₐₐₛ for describing channel space dispersion characteristics of a scatterers distribution in the scenarios, and a root mean square elevation arrival angle spread RMS EAS σₑₐₛ.

In Step S202, in view of the channel characteristic parameters collected in Step S201 and the indoor office communication scenario built in Step S201, channel characteristic parameter vectors and physical environment parameter vectors are defined. And the step includes as follows. The channel characteristic parameter vectors Sₙ are defined as a received power, a root mean square delay spread, a root mean square azimuthal arrival angle spread, and a root mean square elevation arrival angle spread. The physical environment parameter vectors Mₙ are defined as an environmental scatterer density, a transmitting terminal antenna coordinate, and an interval between a receiving terminal and the transmitting terminal. And the obtained formulas are expressed as:

Sₙ=[P,σds,σₐₐₛ,σₑₐₛ]ₙ,n=1,2,3, . . . ,C

Mₙ=[ρₛ,x_{Tx},y_{Tx},z_{Tx},dₘ]_{n′},n=1,2,3, . . . ,C,

where C denotes the total number of the channels in the entire environment, x_{Tx}, y_{Tx}, z_{Tx} denotes a three-dimensional coordinate of the transmitting terminal antenna Tx in the scenario, and dₘ denotes a distance between the transmitting terminal antenna and a receiving terminal antenna Rx.

In Step S203, the channel characteristic parameter vectors Sₙ and the physical environment parameter vectors Mₙ obtained in Step S202 are combined into a channel data vector hₙ, and a formula of the channel data vector is expressed as:

hₙ={Mₙ,Sₙ}.

In Step S204, the data normalization is performed on the channel data vector hₙ obtained in Step S203.

Further, Step S3 specifically includes following steps.

In Step S301, a space correlation of the channel data is calculated. And the step includes as follows. A correlation calculation is performed on a subset for the channel data vector at each time instant, and a distance of the channel data in a physical space is characterized by using a reciprocal of an Euclidean distance between the channel environment parameter vectors Mₙ, to display the space correlation of the channel data.

In Step S302, a highly correlated graph dataset for channel space data is constructed, and the step includes as follows. Values for the number of neighboring nodes N in the graph dataset are set (based on an application scenario of the present disclosure, the value for N is set to 4). Then, N group channel data vectors having a highest space correlation with each group of the channel data vectors are selected to establish a unidirectional edge in the graph dataset, and then a subset for the channel data vectors at each time instant are constructed as a channel spacespace graph dataset at a current time instant.

In Step S303, time series characteristics are added into the channel space graph dataset proposed in Step S302 to construct a channel space-time correlation graph dataset. The step includes as follows. A time series length is set and expressed as k (based on an application scenario of the present disclosure, the value for k is set to 7), that is, a length of k known historical channel characteristic series is taken as one group of channel evolution patterns to extract time characteristics. Then, k+1 space graph datasets are extracted sequentially to construct a channel time series, first k space graph datasets are taken as an input for the predictive model and a last space graph dataset is taken as an output for the predictive model. Thus, a channel space-time dataset is constructed based on additional channel time series characteristics, to provide data supports for subsequent multi-scenario channel predictions.

Further, Step S4 specifically includes following steps. The dataset is divided into the training set, the validation set, and the testing set, which are used for a network training, a network optimization, and a performance evaluation, respectively. In order to avoid an interleaving of channel space-time information between different datasets, 80% of the dataset is divided for training, 10% of the dataset is divided for validation, and 10% of the dataset is divided for testing.

Further, Step S5 specifically includes following steps.

In Step S501, firstly, the channel prediction network based on graph attention network GAT and gated recurrent unit GRU is constructed, and the network parameters for the channel prediction network are initialized. A graph attention network module in a GAT-GRU channel prediction network is a graph attention network with 32 graphic attention layers, channel characteristics with 4 dimensions at one certain time instant are taken as an input, and mapped to 32 dimensions, for extracting space characteristic information in the channel predictions in the GAT network module. A linear unit function Leaky Rectified Linear Unit with a leakage correction is used as an activation function in the graph attention network. A single-layer gated recurrent unit network with 32 hidden units is used in a gated recurrent unit network module in the GAT-GRU channel prediction network, and is configured to extract time characteristic information in the channel predictions. An initialization parameter for the first gated recurrent unit network module is set to 0 to reduce computational complexity.

In Step S502, then, a channel characteristic vector sequence [F]ₜ₋ₖ, [F]ₜ₋ₖ₊₁, [F]ₜ₋₁ in a low density scenario with a scatterer density being ρₛ₁ in the constructed space-time graph dataset for the channel is input into the GAT-GRU network, to perform the channel prediction, and high space-time correlated channel characteristics are input. An input dimension of the GAT-GRU network is 12×4.

In Step S503, the GAT-GRU channel prediction network extracts characteristics from the input channel characteristic vector sequence. In the graph attention network module, space characteristics of channel data in a graph dataset are effectively extracted by aggregating highly correlated neighboring nodes in a space domain, and an output is a cascaded channel characteristic vector [F′] with a dimension of 12×32, the channel characteristic vector is then sent to the gated recurrent unit network module to perform a time characteristic extraction. In the gated recurrent unit network module, the time characteristics of the channel characteristics are extracted from cascaded channel characteristic vectors at different time instants, and an output is a cascaded channel characteristic vector [F′]t with a dimension of 12×32 at a current time instant, the channel characteristic vector contains space-time channel characteristic information.

In Step S504, the cascaded channel characteristic vector after the characteristic extraction is input into a multi-layer perceptron network, and a mean squared logarithmic error mean square log error is taken as a loss function of the network. The parameters for the channel prediction network based on graph attention network GAT and gated recurrent unit GRU are further fine-tuned according to the result. Eventually, a predicted value for the channel statistical characteristics with a dimension of 12×4 at each position in a high-density scenario with a scatterer density being βₛ₂ at a next time instant is obtained.

The method for modeling the scatterer density-based scenario predictive channel provided by the present disclosure has the following advantages. The present disclosure introduces a machine learning algorithm on the basis of a traditional wireless channel modeling and proposes a novel method for modeling the scenario predictive channel based on the scatterer density. The present disclosure is capable of exploring the dynamic evolution of channels in scenarios with different scatterer densities and can predict the channel characteristics of specific scenarios with higher scatterer densities or lower scatterer densities. By trainings for space-time correlated channel data, the proposed model can improve the predictive performance of the scenario channel based on the scatterer density and achieve the relative high predictive accuracy. In addition, the present disclosure can accurately predict channel characteristics in different scenarios, such as the received power and the channel statistical characteristics. In a case using the channels in a scenario with a specific scatterer density to predict channels in other constructed scenarios, the performance is superior to a 3GPP standardized channel model. The present disclosure has good performance in channel prediction based on scenario and can be used for key technologies such as a 6G multi scene system design, a network optimization and a network planning, as well as a resource allocation.

### BRIEF DESCRIPTION OF THE DRAWINGS

FIG. 1 illustrates a flow chart diagram of a novel scatterer density-based predictive channel modeling method provided by the present disclosure.

FIG. 2 illustrates a layout diagram of a transmitter position and a receiver position in a dense scenario channel simulation environment provided by present disclosure.

FIG. 3 illustrates a layout diagram of a transmitter position and a receiver position in a sparse scenario channel simulation environment provided by present disclosure.

FIG. 4 illustrates a schematic diagram of a channel prediction network based on graph attention network GAT and gated recurrent unit GRU flow provided by the present disclosure.

FIG. 5 illustrates a comparison schematic diagram between a predictive result of a trained predictive channel model for a root mean square azimuth arrival angle spread, a RT simulation result, and a simulation result of a 3GPP standardized channel model provided by the present disclosure.

FIG. 6 illustrates a comparison schematic diagram between a predictive result of a trained predictive channel model for a root mean square pitch angle of arrival spread, a RT simulation result, and a simulation result of a 3GPP standardized channel model provided by the present disclosure.

### DETAILED DESCRIPTION OF THE EMBODIMENTS

In order to better understand the objectives, the structures, and the functions of the present disclosure, a method for modeling a scenario predictive channel based on a scatterer density of present disclosure will be further specifically described in conjunction with the accompanying drawings.

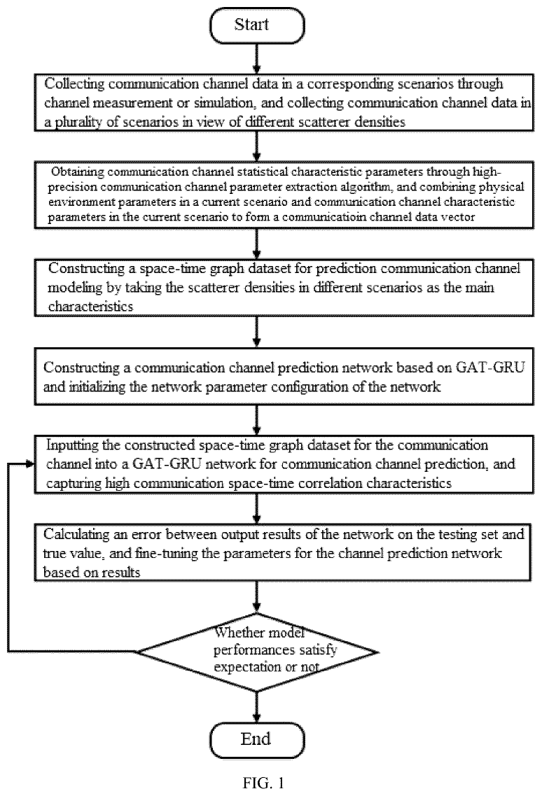

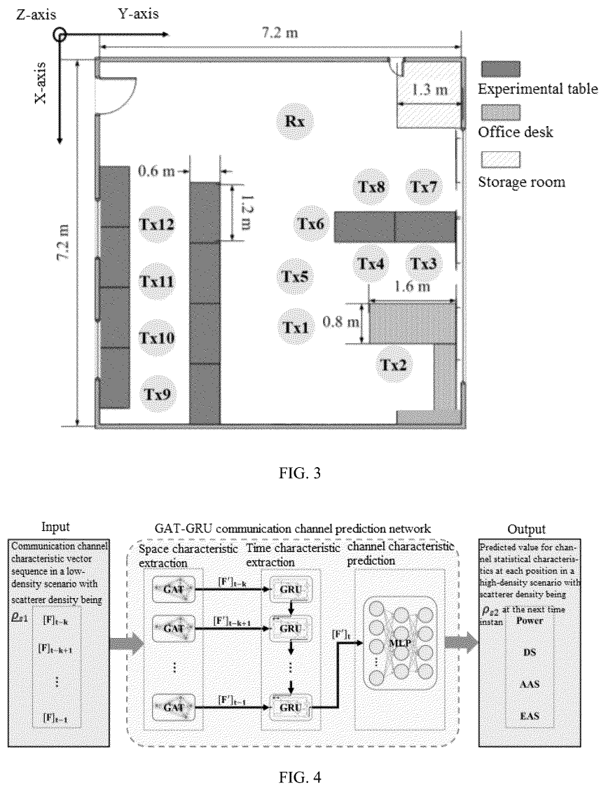

With reference to FIGS. 1 to 6, provided in this embodiment is a method for modeling a scenario predictive channel based on a scatterer density. And the method specifically includes the following steps.

In Step S1, channel data in a corresponding scenario are collected through a channel measurement or a simulation. In view of different scatterer densities, channel data in the plurality of scenarios are collected for subsequent channel prediction experiments.

Specifically, in this embodiment, Step S1 specifically includes following steps.

In Step S101, the channel data are simulated by utilizing a ray tracing RT wireless insite commercial software, indoor office scenarios with different scatterer densities are emulated, and the scatterer densities ρₛ is expressed as:

$${ρ}_{s} = \frac{\sum {S}_{{S}_{i}}}{{S}_{total}} \times 100 \% = \frac{\sum {S}_{{S}_{i}}}{\sum {S}_{{S}_{i}} + {S}_{room}} \times 100 \% ,$$

where Sₜₒₜₐₗ denotes a surface area of an entire scenario, Sₛᵢ denotes a surface area of each of the scatterers in the scenario, Sᵣₒₒₘ denotes a surface area of own rooms in the indoor office, and an entire scatterer density formula expresses a percentage of the scatterers in the communication scenario to surface area of the entire scenario.

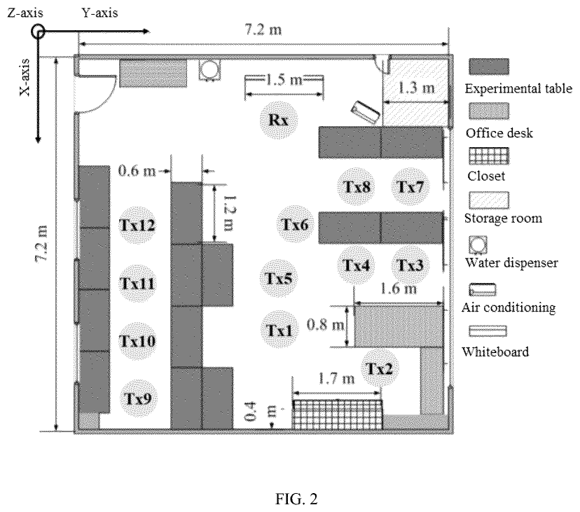

The scatterer density of the simulated communication scenario is 20% and 60%, respectively, in a case of a obtained scatterer density ρₛ₁<40% of a simulated communication scenario, it is defined as a sparse scenario; in a case of a obtained scatterer density ρₛ₂>40% of the simulated communication scenario, it is defined as a dense scenario. Therefore, a sparse scenario and a dense scenario are obtained during the whole simulation for subsequent simulation verification of the predictive modeling, and the simulation modeling scenario diagrams thereof are referenced to FIG. 2 and FIG. 3.

In Step S2, in view of the channel data obtained in Step S1, collected channel measurement data are preprocessed by a high-precision channel parameters extraction algorithm to obtain corresponding channel statistical characteristic parameters. Then, physical environment parameters in a current scenario and channel characteristic parameters in the current scenario are combined to form a channel data vector for constructing a dataset construction subsequently.

Specifically, in this embodiment, Step S2 specifically includes following steps.

In Step S201, high-precision channel characteristic parameters are extracted from collected channel data by using a space-alternating generalized expectation maximization algorithm space-alternating generalized expectation maximization. And the high-precision channel characteristic parameters include a received power P for describing a signal strength that is obtained from an original channel impulse response, a root mean square delay spread RMS DS ρ_{ds} for describing channel time dispersion characteristics, a root mean square azimuthal arrival angle spread RMS AAS σₐₐₛ for describing channel space dispersion characteristics of a scatterers distribution in the scenarios, and a root mean square elevation arrival angle spread RMS EAS σₑₐₛ.

In Step S202, in view of the channel characteristic parameters collected in Step S201 and the indoor office communication scenario built in Step S201, channel characteristic parameter vectors and physical environment parameter vectors are defined. And the step includes as follows. The channel characteristic parameter vectors Sₙ are defined as a received power, a root mean square delay spread, a root mean square azimuthal arrival angle spread, and a root mean square elevation arrival angle spread. The physical environment parameter vectors Mₙ are defined as an environmental scatterer density, a transmitting terminal antenna coordinate, and an interval between a receiving terminal and the transmitting terminal. And the obtained formulas are expressed as:

Sₙ=[P,σds,σₐₐₛ,σₑₐₛ]ₙ,n=1,2,3, . . . ,C

Mₙ=[ρₛ,x_{Tx},y_{Tx},z_{Tx},dₘ]_{n′}n=1,2,3, . . . ,C,

where C denotes the total number of the channels in the entire environment, x_{Tx}, y_{Tx}, z_{Tx} denotes a three-dimensional coordinate of the transmitting terminal antenna Tx in this scenario, and dₘ denotes a distance between the transmitting terminal antenna and a receiving terminal antenna Rx.

In Step S202, the channel characteristic parameter vectors Sₙ and the physical environment parameter vectors Mₙ obtained in Step S202 are combined into a channel data vector hₙ, and a formula of the channel data vector is expressed as:

hₙ={Mₙ,Sₙ}.

In Step S203, the data normalization is performed on the channel data vector hₙ obtained in Step S202. And the step includes as follows. The channel impulse response of the channel measurement data is normalized by using a z-value normalization method:

$$X = \frac{x - μ}{σ} ,$$

where, X are normalized data and x are original measurement data.

In Step S3, a space-time graph dataset for a predictive channel modeling is constructed. The scatterer densities in different scenarios are taken as main characteristics during a network training process, in order to better extract the scatterer densities, in view of the channel data vector obtained in Step S2, space-time correlation of the channel data are enhanced by correlated neighboring nodes and time series, so as to construct the space-time graph dataset for the channel.

Specifically, in this embodiment, Step S3 specifically includes following steps.

In Step S301, a space correlation of the channel data is calculated. And the step includes as follows. A correlation calculation is performed on a subset for the channel data vector at each time instant, and a distance of the channel data in a physical space is characterized by using a reciprocal of an Euclidean distance between the channel environment parameter vectors Mₙ, to display the space correlation of the channel data.

In Step S302, a highly correlated graph dataset for channel space data is constructed, and the step includes as follows. Values for a number of neighboring nodes N in the graph dataset are set (based on an application scenario of the present disclosure, the value for N is set to 4). Then, N group channel data vectors having a highest space correlation with each group of the channel data vectors are selected to establish a unidirectional edge in the graph dataset, and then a subset for the channel data vectors at each time instant are constructed as a channel space graph dataset at a current time instant.

In Step S303, time series characteristics are added into the channel space graph dataset proposed in Step S302 to construct a channel space-time correlation graph dataset. The step includes as follows. A time series length is set and is expressed as k (based on an application scenario of the present disclosure, the value for k is set to 7), that is, a length of k known historical channel characteristic series is taken as one group of channel evolution patterns to extract time characteristics. Then, k+1 space graph datasets are extracted sequentially to construct a channel time series, the first k space graph datasets are taken as an input for the predictive model and the last space graph dataset is taken as an output for the predictive model. Thus, a channel space-time dataset is constructed based on additional channel time series characteristics, to provide data supports for subsequent multi-scenario channel predictions.

In Step S4, the space-time graph dataset for the channel constructed in a specific scatterer density scenario are divided by proportions into a training set, a validation set, and a testing set in proportion, which are taken as inputs of a predictive network.

Specifically, in this embodiment, Step S4 specifically includes following steps. The dataset is divided into the training set, the validation set, and the testing set, which are used for a network training, a network optimization, and a performance evaluation, respectively. In order to avoid an interleaving of channel space-time information between different datasets, 80% of the dataset is divided for training, 10% of the dataset is divided for validation, and 10% of the dataset is divided for testing.

In Step S5, a cross scenario communication predictive training is performed on a channel prediction network based on the graph attention network GAT and the gated recurrent unit GRU. And the training includes as follows. Firstly, the channel prediction network based on GAT-GRU is constructed, and a network parameter configuration of the channel prediction network is initialized. Then, the constructed space-time graph dataset for the channel is input into a GAT-GRU network, to perform the channel prediction, capturing high space-time correlated channel characteristics. An error between output results of the network on the testing set and actual measurement values for the network is calculated, and further the parameters for the channel prediction network based on GAT-GRU are fine-tuned according to a result. Finally, predicted channel characteristics in different scatterer density scenarios in the testing set are obtained, and a cross scenario channel prediction is implemented.

Specifically, in this embodiment, Step S5 specifically includes following steps.

In Step S501, firstly, the channel prediction network based on graph attention network GAT and gated recurrent unit GRU is constructed, and the network parameters for the channel prediction network are initialized. A graph attention network module in a GAT-GRU channel prediction network is a graph attention network with 32 graphic attention layers, channel characteristics with 4 dimensions at one certain time instant are taken as an input, and mapped to 32 dimensions for extracting space characteristic information in the channel predictions in the GAT network module. A linear unit function Leaky Rectified Linear Unit with a leakage correction is used as an activation function in the graph attention network. and the expression of the function is expressed as

$$Leaky ReLU ( x ) = \{ \begin{matrix}x , & x \geq 0 \\ ax , & x < 0\end{matrix} ,$$

where in this embodiment, the negative slope a is set to 0.2.

In addition, a single-layer gated recurrent unit network with 32 hidden units is used in a gated recurrent unit network module in the GAT-G RU channel prediction network, and is configured to extract time characteristic information in the channel predictions. An initialization parameter for a first gated recurrent unit network module is set to 0 to reduce computational complexity.

In Step S502, then, a channel characteristic vector sequence [F]ₜ₋ₖ, [F]ₜ₋ₖ₊₁, ***, [F]ₜ₋₁ in a low density scenario with a scatterer density being ρₛ₁ in the constructed space-time graph dataset for the channel is input into the GAT-GRU network, to perform the channel prediction, and high space-time correlated channel characteristics are input. An input dimension of the GAT-GRU network is 12×4.

In Step S503, the GAT-GRU channel prediction network extracts characteristics from the input channel characteristic vector sequence. In the graph attention network module, space characteristics of channel data in a graph dataset are effectively extracted by aggregating highly correlated neighboring nodes in a space domain, and an output is a cascaded channel characteristic vector [F′] with a dimension of 12×32, the channel characteristic vector is then sent to the gated recurrent unit network module to perform a time characteristic extraction. In the gated recurrent unit network module, the time characteristics of the channel characteristics are extracted from cascaded channel characteristic vectors at different time instants, and an output is a cascaded channel characteristic vector [F′]ₜ with the dimension of 12×32 at a current time instant, the channel characteristic vector contains space-time channel characteristic information.

In Step S504, the cascaded channel characteristic vector that after the characteristic extraction is input into a multi-layer perceptron network, and a mean squared logarithmic error mean square log error is taken as a loss function of the network. The parameters for the channel prediction network based on graph attention network GAT and gated recurrent unit GRU are further fine-tuned according to the result. Eventually, a predicted value for the channel statistical characteristics with a dimension of 12×4 at each position in a high-density scenario with a scatterer density being ρₛ₂ at a next time instant is obtained.

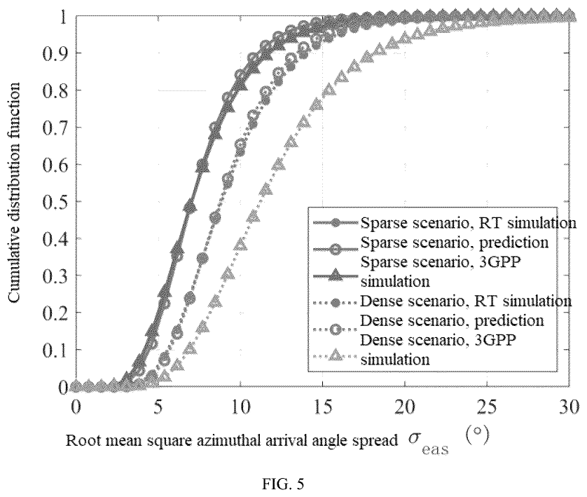

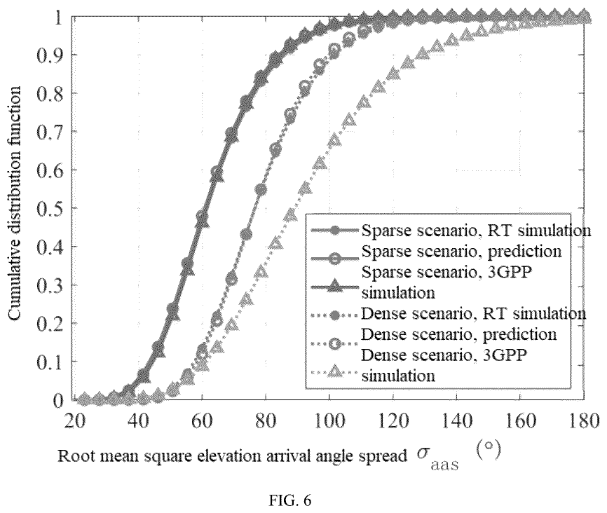

Specifically, in this embodiment, four channel characteristics in a high-density scenario with a scatterer density ρₛ₂ that are obtained by predictive in a predictive channel model, including the received power and three channel statistical characteristics, are compared with the channel characteristics obtained by a RT simulation in a high-density scenario with a scatterer density ρₛ₂ and the channel characteristics obtained by a 3GPP standardized channel model in a high-density scenario with a scatterer density βₛ₂, to analyze the performances of the predictive channel model, and the simulation results are referenced to FIG. 5 and FIG. 6. FIG. 5 illustrates a comparison schematic diagram between a predictive result of a trained predictive channel model for a root mean square azimuth arrival angle spread, a RT simulation result, and a simulation result of a 3GPP standardized channel model. It can be seen from the comparison diagram of the results that the predicted results have a good fit with the channel simulation results, indicating that the predictive model has good predictive performance and is superior to the 3GPP standardized channel model in terms of the root mean square azimuth arrival angle spread. FIG. 6 illustrates a comparison schematic diagram between a predictive result of a trained predictive channel model for a root mean square pitch angle of arrival spread, a RT simulation result, and a simulation result of a 3GPP standardized channel model. It can be seen from the comparison diagram of the results that the predicted results have a good fit with the channel simulation results, indicating that the predictive model has good predictive performance and is superior to the 3GPP standardized channel model in terms of the root mean square pitch angle of arrival spread.

In summary, a method for modeling a scenario predictive channel based on a scatterer density established by the present disclosure is a machine learning-based predictive channel model, which can capture channel variations in the scenarios under different scatterer densities and conduct channel predictions according to the high space-time correlated channel characteristics. The present disclosure constructs a channel space-time graph dataset by capturing the high space-time correlated channel characteristics, to better extract scatterer density variations of the channel characteristics. In order to obtain a well adjusted SDSPCM of the space-time graph dataset based on different scatterer densities, the optimal number of neighboring nodes and the optimal time series length to are provided to implement the optimal predictive performance. The present disclosure has good performance in a term of the channel prediction based on different scenarios and can be used for key technologies such as a 6G multi-scenario system design, a network optimization and a network planning, as well as a resource allocation.

The unspecified parts in the present disclosure are all the common sense for a person skilled in the art.

It should be understood that the present disclosure is described by the plurality of embodiments, and a person skilled in the art aware that various variations and equivalent replacements can be made to these technical characteristics and the embodiments without departing from the spirit and scope of the present disclosure. Furthermore, these technical characteristics and embodiments can be modified to adapt to specific situations and materials without departing from the spirit and scope of the present disclosure under the guidance of the present disclosure. Therefore, the present disclosure is not limited by the specific embodiments disclosed herein, and all embodiments falling within the scope of the claims of the present disclosure are all within the protection scope of the present disclosure.

What is claimed is:

1. A novel scatterer density-based predictive channel modeling method, wherein the method comprises following steps:
Step S1, collecting, through a channel measurement or a simulation, channel data in a corresponding scenario; collecting channel data in a plurality of scenarios in view of different scatterer densities, for subsequent channel prediction experiments;
Step S2, preprocessing, by a high-precision channel parameters extraction algorithm, collected channel measurement data, in view of the channel data obtained in Step S1, to obtain corresponding channel statistical characteristic parameters; then, combining physical environment parameters in a current scenario and channel characteristic parameters in the current scenario to form a channel data vector for constructing a dataset subsequently;
Step S3, constructing a space-time graph dataset for a predictive channel modeling; taking the scatterer densities in different scenarios as main characteristics during a network training process; in order to better extract the scatterer densities, enhancing, by correlated neighboring nodes and time series, space-time correlation of the channel data, in view of the channel data vector obtained in Step S2, to construct the space-time graph dataset for the channel;
Step S4, dividing, in proportion, the space-time graph dataset for the channel constructed in a specific scatterer density scenario in Step S3, into a training set, a validation set, and a testing set, and taking the training set, the validation set, and the testing set as inputs of a predictive network; and
Step S5, performing a cross scenario communication predictive training on a channel prediction network based on a graph attention network GAT and a gated recurrent unit GRU, and the training including: firstly, constructing the channel prediction network based on GAT-GRU, and initializing a network parameter configuration of the channel prediction network; then, inputting the constructed space-time graph dataset for the channel into a GAT-GRU network, to perform the channel prediction, capturing high space-time correlated channel characteristics; calculating an error between output results of the network on the testing set and actual measurement values for the network, further fine-tuning, according to a result, parameters for the channel prediction network based on GAT-GRU; and finally obtaining predicted channel characteristics in different scatterer density scenarios in the testing set, and implementing a cross scenario channel prediction.

2. The novel scatterer density-based predictive channel modeling method according to claim 1, wherein Step S1 specifically includes:
Step S101, simulating, by utilizing a ray tracing RT software, the channel data, emulating indoor office scenarios with different scatterer densities, and defining the scatterer densities ρ_{S} as:
$${ρ}_{s} = \frac{\sum {S}_{{S}_{i}}}{{S}_{total}} \times 100 \% = \frac{\sum {S}_{{S}_{i}}}{\sum {S}_{{S}_{i}} + {S}_{room}} \times 100 \% ,$$
where Sₜₒₜₐₗ denotes a surface area of an entire scenario, Sₛᵢ denotes a surface area of each of the scatterers in the scenario, Sᵣₒₒₘ denotes a surface area of own rooms in the indoor office, and an entire scatterer density formula expresses a percentage of the scatterers in the communication scenario to surface area of the entire scenario; and
defining, in a case of a obtained scatterer density ρₛ₁<40% of a simulated communication scenario, as a sparse scenario, defining, in a case of a obtained scatterer density ρₛ₂>40% of the simulated communication scenario, as a dense scenario.

3. The novel scatterer density-based predictive channel modeling method according to claim 2, wherein Step S2 specifically includes:
Step S201, extracting, by using a space-alternating generalized expectation maximization algorithm space-alternating generalized expectation maximization, high-precision channel characteristic parameters, from collected channel data, wherein the high-precision channel characteristic parameters include: a received power P for describing a signal strength that is obtained from an original channel impulse response, a root mean square delay spread RMS DS σ_{ds} for describing channel time dispersion characteristics, a root mean square azimuthal arrival angle spread RMS AAS σₐₐₛ for describing channel space dispersion characteristics of a Scatterers distribution in the scenarios, and a root mean square elevation arrival angle spread RMS EAS σₑₐₛ;
Step S202, defining, in view of the channel characteristic parameters collected in Step S201 and the indoor office communication scenario built in Step S201, channel characteristic parameter vectors and physical environment parameter vectors, and the step including: defining the channel characteristic parameter vectors Sₙ as a received power, a root mean square delay spread, a root mean square azimuthal arrival angle spread, and a root mean square elevation arrival angle spread; and defining the physical environment parameter vectors Mₙ as an environmental scatterer density, a transmitting terminal antenna coordinate, and an interval between a receiving terminal and the transmitting terminal; and expressing obtained formulas as:
Sₙ=[P,σds,σₐₐₛ,σₑₐₛ]ₙ,n=1,2,3, . . . ,C
Mₙ=[ρₛ,x_{Tx},y_{Tx},z_{Tx},dₘ]_{n′}n=1,2,3, . . . ,C,
where C denotes a total number of the channels in the entire environment, x_{Tx}, y_{Tx}, z_{T} denotes a three-dimensional coordinate of the transmitting terminal antenna Tx in the scenario, and dₘ denotes a distance between the transmitting terminal antenna and a receiving terminal antenna Rx;
Step S203, combining the channel characteristic parameter vectors Sₙ and the physical environment parameter vectors Mₙ obtained in Step S202 into a channel data vector hₙ, and expressing a formula of the channel data vector as
hₙ={Mₙ,Sₙ}, and
Step S204, performing data normalization on the channel data vector hₙ obtained in Step S203.

4. The novel scatterer density-based predictive channel modeling method according to claim 3, wherein Step S3 specifically includes:
Step S301, calculating a space correlation of the channel data, and the step including: performing a correlation calculation on a subset for the channel data vector at each time instant, and characterizing, by using a reciprocal of an Euclidean distance between the channel environment parameter vectors Mₙ, a distance of the channel data in a physical space, to display the space correlation of the channel data;
Step S302, constructing a highly correlated graph dataset for channel space data, and the step including: setting values for a number of neighboring nodes N in the graph dataset, then, selecting N group channel data vectors having a highest space correlation with each group of the channel data vectors to establish a unidirectional edge in the graph dataset, and then constructing a subset for the channel data vectors at each time instant as a channel space graph dataset at a current time instant;
Step S303, adding time series characteristics into the channel space graph dataset proposed in Step S302, to construct a channel space-time correlation graph dataset, and the step including: setting a time series length and expressing the time series length as k, that is, taking a length of k known historical channel characteristic series as one group of channel evolution patterns to extract time characteristics; then, sequentially extracting k+1 space graph datasets to construct a channel time series, wherein first k space graph datasets are taken as an input for the predictive model and a last space graph dataset is taken as as an output for the predictive model; thus, constructing a channel space-time dataset based on additional channel time series characteristics, and providing data supports for subsequent multi-scenario channel predictions.

5. The novel scatterer density-based predictive channel modeling method according to claim 4, wherein Step S4 specifically includes: dividing the dataset into the training set, the validation set, and the testing set, for a network training, a network optimization, and a performance evaluation, respectively; and dividing 80% of the dataset for training, 10% of the dataset for validation, and 10% of the dataset for testing, to avoid an interleaving of channel space-time information between different datasets.

6. The novel scatterer density-based predictive channel modeling method according to claim 4, wherein Step S5 specifically includes:
Step S501, firstly, constructing the channel prediction network based on GAT-GRU, and initializing the network parameters for the channel prediction network; wherein a graph attention network module is a graph attention network with 32 graphic attention layers, channel characteristics with 4 dimensions at one certain time instant are taken as as an input, and mapped to 32 dimensions, for extracting space characteristic information in the channel predictions in a channel prediction network GAT-GRU; a linear unit function Leaky Rectified Linear Unit with a leakage correction is used as an activation function in the graph attention network; a single-layer gated recurrent unit network with 32 hidden units is used in a gated recurrent unit network module in the GAT-GRU channel prediction network, and is configured to extract time characteristic information in the channel predictions; and an initialization parameter for a first gated recurrent unit network module is set to 0 to reduce computational complexity;
Step S502, then, inputting a channel characteristic vector sequence [F]ₜ₋ₖ, [F]ₜ₋ₖ₊₁, * * * , [F]ₜ₋₁ in a low density scenario with a scatterer density being ρₛ₁ in the constructed space-time graph dataset for the channel into the GAT-GRU network, to perform the channel prediction, and capturing high space-time correlated channel characteristics; wherein an input dimension of the GAT-GRU network is 12×4;
Step S503, extracting, through the GAT-GRU channel prediction network, characteristics from the input channel characteristic vector sequence; wherein in the graph attention network module, space characteristics of channel data in a graph dataset are effectively extracted by aggregating highly correlated neighboring nodes in a space domain, and an output is a cascaded channel characteristic vector [F′] with a dimension of 12×32, the channel characteristic vector is then sent to the gated recurrent unit network module to perform a time characteristic extraction; in the gated recurrent unit network module, the time characteristics of the channel characteristics are extracted from cascaded channel characteristic vectors at different time instants, and an output is a cascaded channel characteristic vector [F′]ₜ with a dimension of 12×32 at a current time instant, the channel characteristic vector contains space-time channel characteristic information; and
Step S504, inputting the cascaded channel characteristic vector after the characteristic extraction into a multi-layer perceptron network, and taking a mean squared logarithmic error mean square log error as a loss function of the network, further fine-tuning, according to the result, the parameters for the channel prediction network based on graph attention network GAT and gated recurrent unit GRU, and eventually obtaining a predicted value for the channel statistical characteristics with a dimension of 12×4 at each position in a high-density scenario with a scatterer density being ρₛ₂ at a next time instant.
